(19) United States
(12) Patent Application Publication
(10) Pub. No.: US 2025/0279759 A1
(43) Pub. Date: Sep. 4, 2025

(54) MULTIBAND BALUN

(71) Applicant: NEC Corporation, Tokyo (JP)

(72) Inventor: Hajime SAKAI, Tokyo (JP)

(73) Assignee: NEC Corporation, Tokyo (JP)

(21) Appl. No.: 19/057,047

(22) Filed: Feb. 19, 2025

(30) Foreign Application Priority Data
Mar. 1, 2024 (JP) 2024-031379

(51) Int. Cl. H03H 7/42

(52) U.S. Cl. CPC H03H 7/42

(57) ABSTRACT

A multiband balun includes a first balanced line, one end of the first balanced line being grounded and an other end of the first balanced line being connected to a balanced terminal, the balanced terminal being connected to a balanced circuit; a second balanced line, one end of the second balanced line being grounded and an other end of the second balanced line being connected to a balanced terminal, the balanced terminal being connected to the balanced circuit; an unbalanced line, one end of the unbalanced line being connected to an unbalanced terminal, the unbalanced terminal being connected to an unbalanced circuit; and a first switch, wherein the first switch switches a state of an unbalanced termination to one of an open state and a ground state and the unbalanced termination is one end of the unbalanced line opposite the one end connected to the unbalanced terminal.

### FIELD

### Cross Reference to Related Applications

This application is based upon and claims the benefit of the priority of Japanese patent application No. 2024-031379, filed on Mar. 1, 2024, the disclosure of which is incorporated herein in its entirety by reference thereto.

The present disclosure relates to a multiband balun.

### BACKGROUND

There is a balun connecting a balanced circuit to an unbalanced circuit. As a high fractional bandwidth, low-loss balun, there is a Marchand balun that uses coupled lines. Marchand balun is, for example, provided with a first short stub SS1 and a second short stub SS2 and an open stub OS, as illustrated in FIG. 15A. The first short stub SS1 and the second short stub SS2 each have a length of ¼ wavelength of an operation wavelength 2, which is a wavelength corresponding to an operation frequency. The open stub OS has a length of ½ wavelength of the operation wavelength λ.

For the 5th Generation Mobile Communication System (5G) and the next generation Beyond 5G (so-called 6G), multi-banding has an aspect of increasing communications capacity and flexibility. This has led to an increase in demand for multiband baluns that can handle signals of multiple frequency bands.

As a technique for varying a bandwidth of a circuit element having coupled lines, referring to for example, Patent Literature (PTL) 1, there is a band variable filter that allows wide-band variation of a center frequency. The band variable filter disclosed in PTL1 is provided with a coupled line having two transmission lines and further at least one switching element. The switching element is connected to a part of two transmission lines and can be switched on and off to change the length of the coupled lines, thereby changing the center frequency. With this technology, the length of the coupled lines can be changed by switching the switching element. Therefore, it is easy to realize a band variable filter that allows wide-band variation of the center frequency.

[PTL 1] Japanese Patent Kokai Publication No. 2010-124311 A

### SUMMARY

The following analysis has been made by the present inventor.

For example, by applying the technology of the PTL 1 to balun, i.e., by making the coupled line length variable, a balun that can support multiple bandwidths can be realized. However, according to the technique disclosed in PTL 1, in order to make the coupled line length variable, it is necessary to add a new coupled line ADD, as illustrated in FIG. 15B. Therefore, the circuit area of the balun becomes larger by that much. This cannot respond to the miniaturization of device, which is highly demanded along with a shift to multiband.

The present disclosure is made in view of the above circumstances. It is an object of the present disclosure to provide a multiband balun with a small area and variable bandwidth.

According to a first aspect of the present disclosure, there is provided a multiband balun including:
a first balanced line, one end of the first balanced line being grounded and an other end of the first balanced line being connected to a balanced terminal, the balanced terminal being connected to a balanced circuit;
a second balanced line, one end of the second balanced line being grounded and an other end of the second balanced line being connected to a balanced terminal, the balanced terminal being connected to the balanced circuit;
an unbalanced line, one end of the unbalanced line being connected to an unbalanced terminal, the unbalanced terminal being connected to an unbalanced circuit; and
a first switch, wherein
the first switch switches a state of an unbalanced termination to one of an open state and a ground state, the unbalanced termination being one end of the unbalanced line opposite the one end connected to the unbalanced terminal.

According to the present disclosure, it is possible to provide a multiband balun with a small area and variable bandwidth.

### BRIEF DESCRIPTION OF DRAWINGS

FIG. 1A is a schematic block diagram of a Marchand balun according to the present disclosure.

FIGS. 1B and 1C are schematic block diagrams of a transformer type balun according to the present disclosure.

FIG. 2 is a diagram illustrating frequency characteristics of the Marchand balun and the transformer type balun according to the present disclosure.

FIG. 3A is a schematic block diagram of an example of a multiband balun according to an example embodiment of the present disclosure.

FIG. 3B is a table illustrating an operation mode for each state of a type conversion switch of the multiband balun.

FIG. 3C is a diagram illustrating a frequency characteristic of each operation mode of the multiband balun.

FIG. 4 is a diagram illustrating an example of a control mode of a type conversion switch of the multiband balun according to the example embodiment of the present disclosure.

FIGS. 5A to 5D are schematic block diagrams of examples of multiband baluns according to other example embodiments of the present disclosure, respectively.

FIG. 6A is a diagram illustrating a frequency characteristic of a multiband balun according to other example embodiment of the present disclosure.

FIG. 6B is a table illustrating a configuration example for each operation mode of a multiband balun according to other example embodiment of the present disclosure.

FIG. 7A is a schematic block diagram of an example of a multiband balun according to other example embodiment of the present disclosure.

FIG. 7B is a table illustrating an operation mode for each state of a type conversion switch of the multiband balun.

FIG. 7C is a diagram illustrating a frequency characteristic of each operation mode of the multiband balun.

FIG. 8A is a schematic block diagram of an example of a multiband balun according to other example embodiment of the present disclosure.

FIG. 8B is a table illustrating an operation mode for each state of a type conversion switch of the multiband balun.

FIG. 8C is a diagram illustrating a frequency characteristic of each operation mode of the multiband balun.

FIG. 9A is a schematic block diagram of an example of a multiband balun according to other example embodiment of the present disclosure.

FIG. 9B is a table illustrating an operation mode for each state of a type conversion switch of the multiband balun.

FIG. 9C is a diagram illustrating a frequency characteristic of each operation mode of the multiband balun.

FIG. 10A is a schematic block diagram of an example of a multiband balun according to other example embodiment of the present disclosure.

FIG. 10B is a table illustrating an operation mode for each state of a type conversion switch of the multiband balun.

FIG. 10C is a diagram illustrating a frequency characteristic of each operation mode of the multiband balun.

FIG. 11A is a schematic block diagram of an example of a multiband balun according to other example embodiment of the present disclosure.

FIG. 11B is a table illustrating an operation mode for each state of a type conversion switch of the multiband balun.

FIG. 11C is a diagram illustrating a frequency characteristic of each operation mode of the multiband balun.

FIG. 12A is a schematic block diagram of an example of a multiband balun according to other example embodiment of the present disclosure.

FIG. 12B is a table illustrating an operation mode for each state of a type conversion switch of the multiband balun.

FIG. 12C is a diagram illustrating a frequency characteristic of each operation mode of the multiband balun.

FIG. 13A is a schematic block diagram of an example of a multiband balun according to other example embodiment of the present disclosure.

FIG. 13B is a table illustrating an operation mode for each state of a type conversion switch of the multiband balun.

FIG. 13C is a diagram illustrating a frequency characteristic of each operation mode of the multiband balun.

FIG. 14 is a schematic block diagram of an example of a multiband balun according to a variation example of the present disclosure.

FIG. 15A is a diagram illustrating a schematic configuration of a conventional Marchand balun.

FIG. 15B is a diagram illustrating a frequency adjustment of the conventional Marchand balun.

### EXAMPLE EMBODIMENTS

Prior to describing an example embodiment to which the present disclosure applies, a balun connecting a balanced circuit to an unbalanced circuit is explained. The present disclosure is not limited to the following example embodiment, but may be modified in various ways without departing from a gist of the present disclosure. Also, the drawings are schematic drawings, and dimensional relationships of respective elements, ratios of respective elements etc. may be different from those in reality. Specific dimensions and other details should be determined with reference to following description. Interactions between drawings may also include parts that have different mutual dimensional relationships and ratios. Note that reference signs in the drawings are for the sake of convenience for each element as an example to promote better understanding and are not intended to limit the present disclosure to a manner illustrated. Unidirectional arrows indicating flow of signals and connection relationship of each element in the drawings are intended to show direction of flow of certain signals and data in a straightforward manner, and do not exclude bidirectionality.

As a type of balun, a Marchand balun 910 is known. The Marchand balun 910 is a balun that can mutually convert a signal between balanced and unbalanced through electromagnetic field coupling.

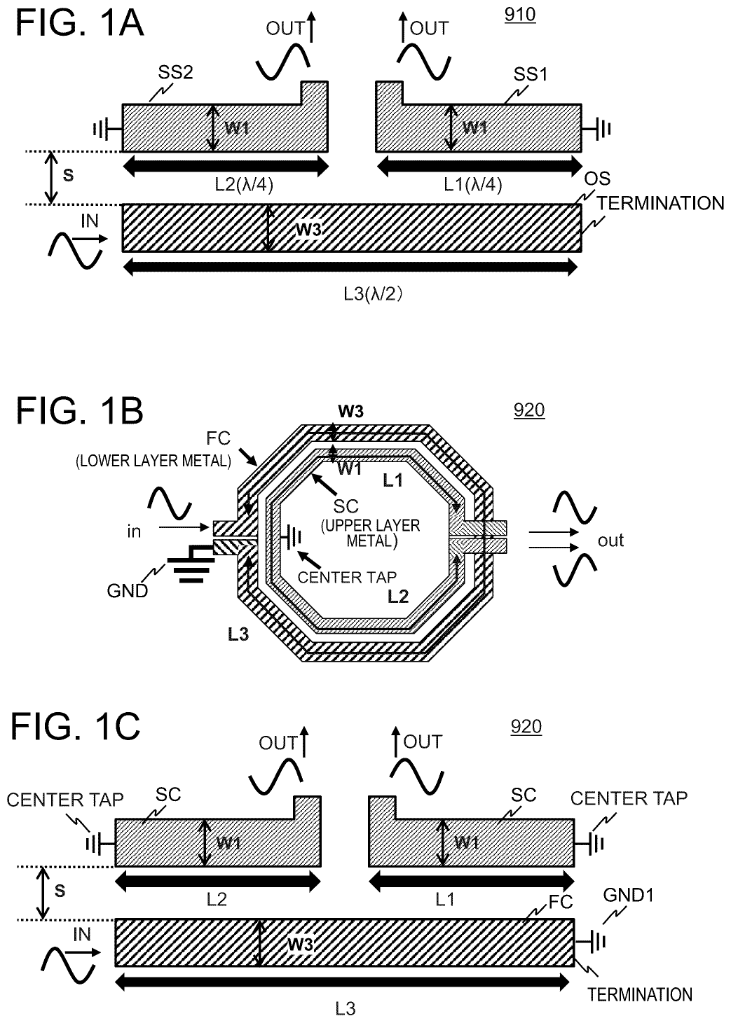

An example of the Marchand balun 910 is illustrated in FIG. 1A. As illustrated in the drawing, the Marchand balun 910 is provided with an open stub OS (coupled line), a first short stub SS1, and a second short stub SS2 (coupled line). The open stub OS is an unbalanced line having a length L3 of a half-wavelength (λ/2) of a wavelength λ corresponding to an operation frequency. The first short stub SS1 and the second short stub SS2 are balanced lines having lengths L1 and L2 of one quarter-wavelength (λ/4), respectively. In a case where there is no need to distinguish between the first short stub SS1 and the second short stub SS2, they are referred to as a short stub SS. In the Marchand balun 910, a termination (unbalanced termination) of the open stub OS, which is an unbalanced line, is an open state. The termination is an end portion opposite the one end connected to an input/output terminal.

The open stub OS and the short stub SS, for example, are made of wiring metal. Therefore, for example, the short stub SS is also called an upper layer metal and the open stub OS is also called a lower layer metal. In FIG. 1A, W1 and W3 are line widths of the short stub SS and the open stub OS, respectively. L1, L2, and L3 are line lengths of the first short stub SS1, the second short stub SS2, and the open stub OS, respectively. S is a coupled line spacing.

There is a transformer type balun 920, as another type of balun. The transformer type balun 920 is a balun that can mutually convert a signal between balanced and unbalanced by magnetic coupling of a primary coil and a secondary coil.

An example of the transformer type balun 920 is illustrated in FIG. 1B. The transformer type balun 920 is provided with a primary coil FC (unbalanced line: lower layer metal) and a secondary coil SC (balanced line: upper layer metal) as illustrated in the drawing. FIG. 1C is a diagram schematically illustrating a configuration of the transformer type balun 920 as well as the Marchand balun 910. As illustrated in the drawing, in the transformer type balun 920, a termination (unbalanced termination) is a ground state (GND). The termination is an end portion opposite of one end connected to an input/output terminal, of the primary coil FC, which is the unbalanced line.

As can be seen from FIG. 1A and FIG. 1C, the only difference between the Marchand balun 910 and the transformer type balun 920 is whether the unbalanced termination of the unbalanced line is open state or ground state.

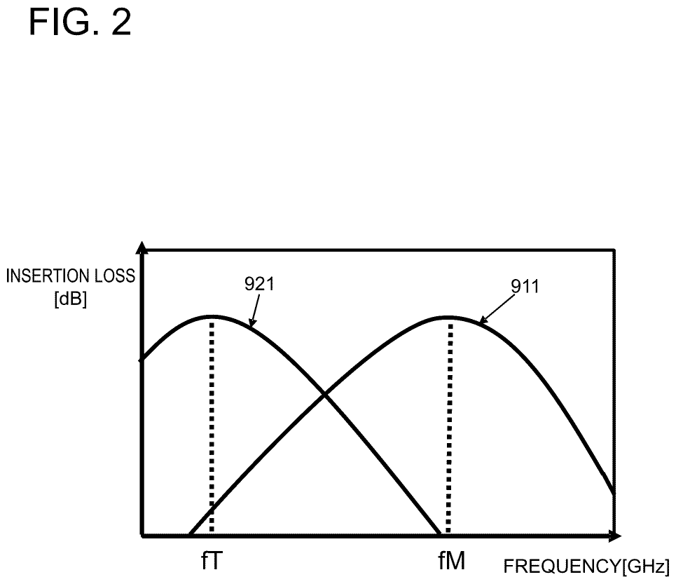

However, in a case where the Marchand balun 910 and the transformer type balun 920 are manufactured with the same line length, comparing an insertion loss (dB) of each, a frequency at a peak is different. Concretely, for example, in a case where L1 and L2 are manufactured with 520 μm and L3 is manufactured with 1040 μm, a frequency characteristic 911 of the Marchand balun 910 and a frequency characteristic 921 of the transformer type balun 920 are illustrated in FIG. 2. As illustrated in the drawing, the frequency at the peak fM (GHz) of the Marchand balun 910 is higher than the frequency at the peak fT (GHz) of the transformer type balun 920.

The frequency at the peak of the frequency characteristic is hereinafter referred to as a center frequency. The center frequency is uniquely determined by line lengths L1, L2, L3, line widths W1, W2, coupled line spacing S, etc. The center frequency is a pass band frequency of each balun. As mentioned above, the center frequency fT (GHz) of the transformer type balun 920 is lower than the center frequency fM (GHz) of the Marchand balun 910 in a case where they are designed with the same dimensions. In other words, the pass band frequency differs depending on the type of balun.

In the present disclosure, this is used to realize a multiband balun that can support multiple different center frequencies (pass band frequencies). Concretely, a state of the unbalanced termination of the unbalanced line is configured to be changeable between the open state and the ground state. Then, by operating as a Marchand balun and a transformer type balun, a multiband balun that can support signals of several different frequency bands is realized.

### First Example Embodiment

The first example embodiment of a multiband balun to which the present disclosure applies is described with reference to the drawings. The multiband balun 110 of the present example embodiment is configured to be able to change a state of the termination of the unbalanced line between the open state and the ground state and operates thereof as a Marchand balun and a transformer type balun. This allows the multiband balun 110 to support signals of two different frequency bands.

### [Configuration]

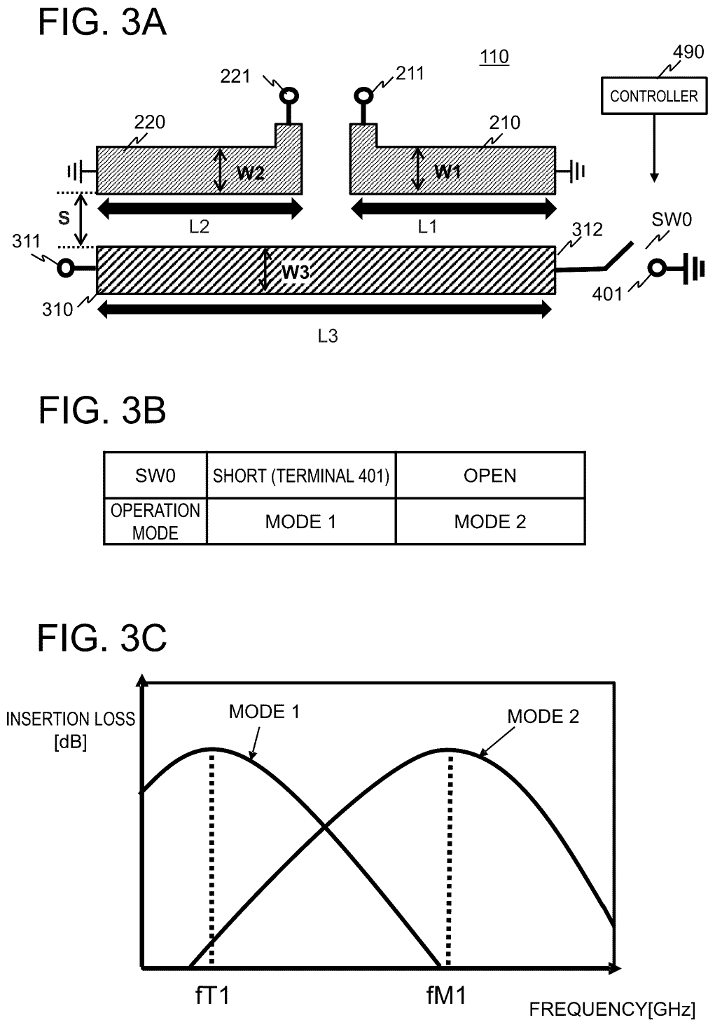

FIG. 3A is a schematic block diagram illustrating a multiband balun 110 of the present example embodiment. As illustrated in the drawing, the multiband balun 110 of the present example embodiment is provided with a first balanced line 210, a second balanced line 220, an unbalanced line 310, an unbalanced terminal 311, a first balanced terminal 211, a second balanced terminal 221, and a type conversion switch (first switch) SW0.

One end of the first balanced line 210 is grounded and the other end thereof is connected to the first balanced terminal 211, which is connected to a balanced circuit. One end of the second balanced line 220 is grounded and the other end thereof is connected to the second balanced terminal 221, which is connected to the balanced circuit.

One end (first end) of the unbalanced line 310 is connected to the unbalanced terminal 311, which is connected to an unbalanced circuit.

The type conversion switch SW0 is connected to an unbalanced termination 312 of the unbalanced line 310. The unbalanced termination 312 is an other end (second end) opposite the one end (first end), which is connected to the unbalanced terminal 311.

The multiband balun 110 of the present example embodiment converts an unbalanced input signal input from the unbalanced terminal 311 into a balanced output signal with a desired frequency component passed therethrough, and outputs it from the first balanced terminal 211 and the second balanced terminal 221. The multiband balun 110 converts a balanced input signal input from the first balanced terminal 211 and/or the second balanced terminal 221 into an unbalanced output signal, and outputs it from the unbalanced terminal 311.

The type conversion switch SW0 switches a state of the unbalanced termination 312 to either an open state or a ground state with respect to a high frequency signal. That is, the type conversion switch SW0 switches a type of the multiband balun 110 between Marchand type and transformer type.

Concretely, the type conversion switch SW0 is provided with a ground terminal 401. Then, the type conversion switch SW0 switches the unbalanced termination 312 between a state in which it is connected to a ground terminal 401 and a state in which it is not connected to the ground terminal 401 (open state), according to a control signal from a controller 490. The state in which the type conversion switch SW0 is connected to the ground terminal 401 is called short, and the state in which the type conversion switch SW0 is not connected to the ground terminal 401 is called open.

The controller 490 operates the type conversion switch SW0 by transmitting the control signal to the type conversion switch SW0 to switch an operation mode of the multiband balun 110 of the present example embodiment.

Here, a line length of the first balanced line 210 is L1, a line length of the second balanced line 220 is L2, and a line length of the unbalanced line 310 is L3. A line width of the first balanced line 210 is W1, a line width of the second balanced line 220 is W2, and a line width of the unbalanced line 310 is W3. A coupled line spacing is S. The coupled line spacing is a spacing between the first balanced line 210 or the second balanced line 220 and the unbalanced line 310. Each line width W1, W2, and W3 may be the same or different. Line lengths L1 and L2 may also be the same or different.

### [Operation]

The following describes each operation mode realized by an operation of the type conversion switch SW0 under the control of the controller 490. FIG. 3B illustrates an operation mode for each state of the type conversion switch SW0 of the multiband balun 110. FIG. 3C illustrates a frequency characteristic of the multiband balun 110 at each operation mode.

In a case where the type conversion switch SW0 is connected to the ground terminal 401 (short) and the unbalanced termination 312 of the unbalanced line 310 is the ground state, the operation mode thereof is called MODE 1. At this time, the multiband balun 110 operates as a transformer type balun that can mutually convert signals between balanced and unbalanced by the magnetic coupling of a primary coil and a secondary coil. Concretely, the first balanced line 210 and the second balanced line 220 function as the primary coil with center-tapped and a line length L1+L2. The unbalanced line 310 functions as a secondary coil with line length L3. The frequency characteristic of the multiband balun 110 in a case where the operation mode thereof is MODE 1 is illustrated in FIG. 3C, and the center frequency thereof is fT1 (GHz) (units are hereinafter omitted). The center frequency fT1 is uniquely determined by dimensional conditions such as line length L1, L2, L3, line width W1, W2, W3, coupled line spacing S, etc.

In a case where the type conversion switch SW0 is unconnected (open) to the ground terminal 401 and the unbalanced termination 312 of the unbalanced line 310, the operation mode thereof is called MODE 2. At this time, the multiband balun 110 operates as a Marchand balun that can mutually convert signals between balanced and unbalanced by coupled lines. Concretely, the first balanced line 210 and the second balanced line 220 function as short stubs with line lengths L1 and L2, respectively. The unbalanced line 310 functions as an open stub with line length L3. The frequency characteristic of the multiband balun 110 in a case where the operation mode thereof is MODE 2 is illustrated in FIG. 3C, and a center frequency thereof is fM1. The center frequency fM1 is uniquely determined by dimensional conditions such as line length L1, L2, L3, line width W1, W2, W3, coupled line spacing S, etc.

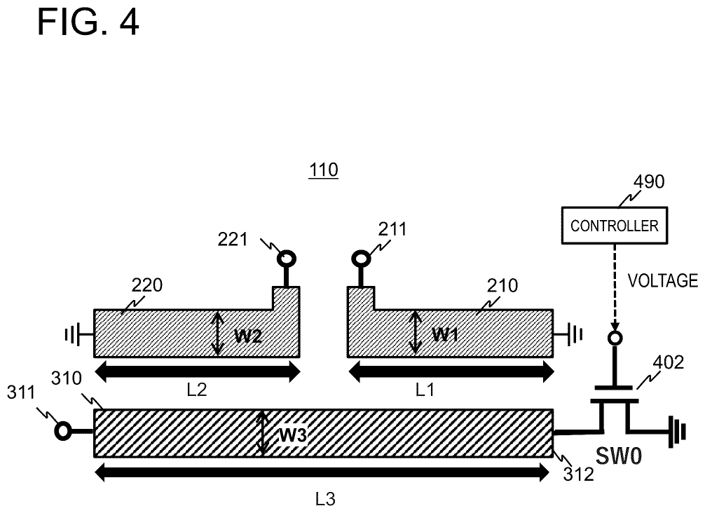

For example, a FET (Field Effect Transistor) 402 may be used for the type conversion switch SW0. An example configuration using the FET 402 for the type conversion switch SW0 is illustrated in FIG. 4. In this case, the control signal from the controller 490 is a voltage (gate bias voltage).

The FET 402 becomes ON state if an applied gate bias voltage exceeds a threshold value. In the ON state, the type conversion switch SW0 is in a short state and the unbalanced termination 312 of the unbalanced line 310 is in the ground state. The FET 402 becomes OFF state if an applied gate bias voltage is lower than the threshold value. In the OFF state, the type conversion switch SW0 is in an open state and the unbalanced termination 312 of the unbalanced line 310 is in an open state.

As explained above, the multiband balun 110 of the present example embodiment is provided with the type conversion switch SW0 that can switch a state of the unbalanced termination 312 of the unbalanced line 310 between the open state and the ground state. By switching the type conversion switch SW0 according to the control signal from the controller 490, the multiband balun 110 can be operated as one of a transformer type balun and a Marchand balun.

As mentioned above, in general, for a transformer type balun and a Marchand balun manufactured with the same line length, line width, and coupled line spacing, the center frequency fT1 of the former is lower than that of the latter (fT1<fM1). In other words, their center frequencies fT1 and fM1 are different.

Therefore, the multiband balun 110 of the present example embodiment is provided with a type conversion switch SW0 and can change the center frequency thereof by switching the type conversion switch SW0 with the control signal from the controller 490. In other words, the multiband balun 110 can support two different pass band frequencies.

In addition, the multiband balun 110 of the present example embodiment only adds the type conversion switch SW0 to the unbalanced termination 312 of the unbalanced line 310 as a circuit configuration. Therefore, the multiband balun 110 does not increase a circuit area. Thus, according to the present example embodiment, a multiband balun with a small area and variable bandwidth can be realized.

### Other Example Embodiments

In general, a center frequency of a balun increases as its line length becomes shorter. In other words, the center frequency changes with line length. In each of the following example embodiments, the multiband balun is configured to be able to support multiple pass band frequencies by further combining this property. In each of the following example embodiments, the line length is varied between a line length which is originally designed (first line length) and a second line length which is shorter than the first line length. This enables the multiband balun to support signals of multiple frequency bands without adding new line lengths.

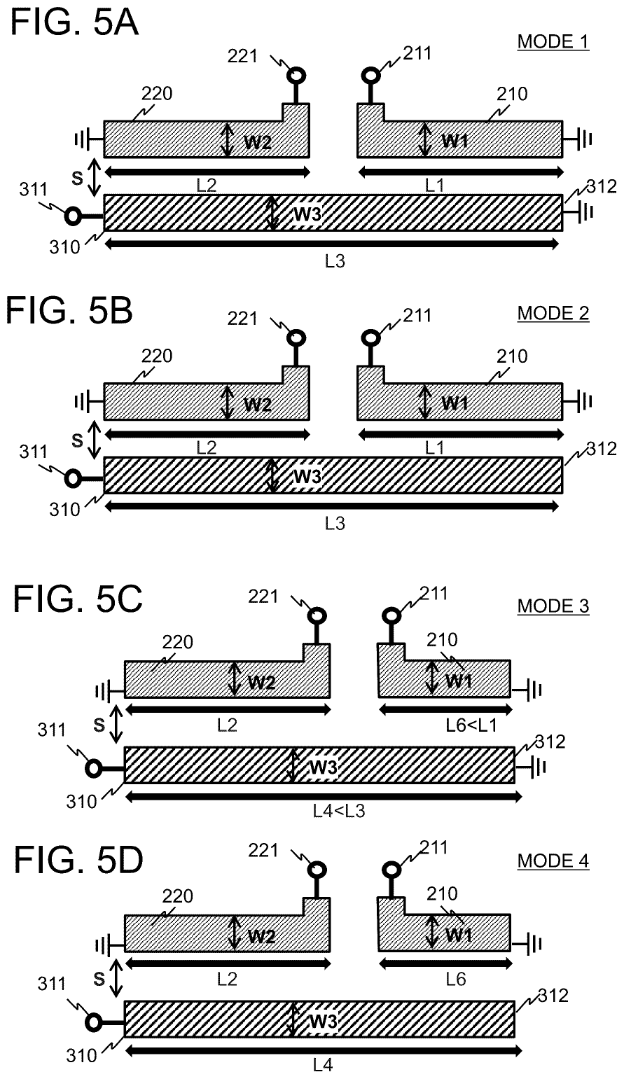

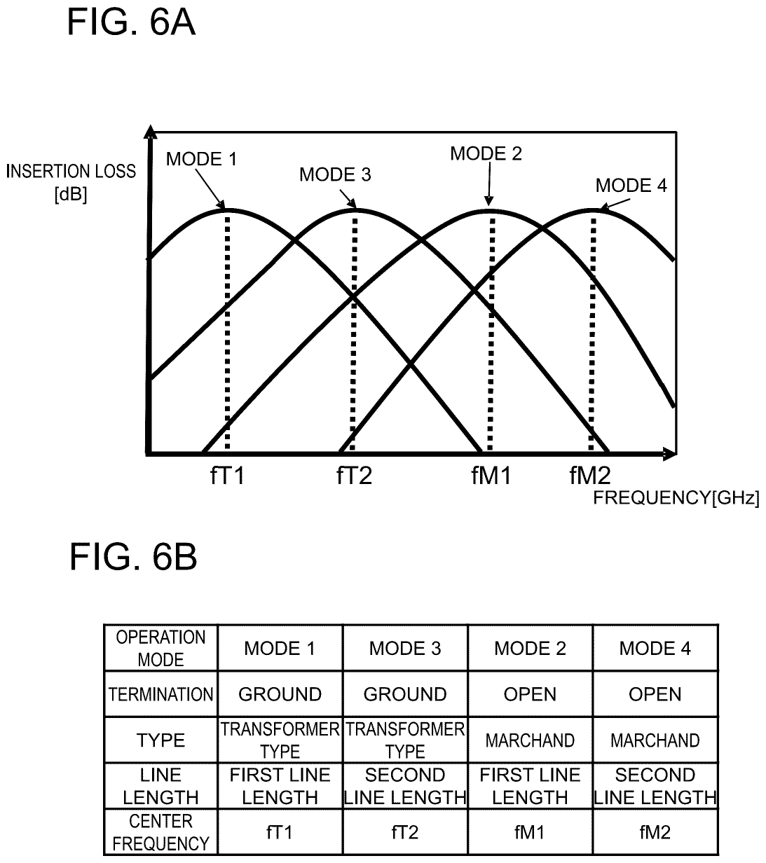

First, possible operation modes of the multiband baluns in each of the following example embodiments are explained using FIG. 5A to FIG. 5D, FIG. 6A and FIG. 6B

In the following example embodiment, a type and line length conversion switch changes a line length of the unbalanced line 310 between a first line length L3 and a second line length L4, which is shorter than the first line length L3, in addition to switching a type, as illustrated in these drawings. At this time, a line length of the first balanced line 210 is changed accordingly between L1 and L6, which is shorter than L1. The second line length L4 is L4<L3.

As illustrated in FIG. 5A, in a case where the line length of the unbalanced line 310 is the first line length L3 and the unbalanced termination 312 of the unbalanced line 310 is the ground state, the operation mode thereof is called MODE 1. This is the same configuration as MODE 1 of the first example embodiment. In this operation mode, the multiband balun operates as a transformer type balun. A balun that operates in this operation mode is called a first line length transformer type balun. A center frequency of a frequency characteristic of the first line length transformer type balun (MODE 1) is set to fT1 as illustrated in FIG. 6A.

As illustrated in FIG. 5B, in a case where the line length of the unbalanced line 310 is the first line length L3 and the unbalanced termination 312 of the unbalanced line 310 is in the open state, the operation mode thereof is called MODE 2. This is the same configuration as MODE 2 of the first example embodiment. In this operation mode, the multiband balun operates as a Marchand balun. A balun that operates in this operation mode is called a first line length Marchand balun. A center frequency of a frequency characteristic of the first line length Marchand balun (MODE 2) is set to fM1 as illustrated in FIG. 6A. As explained in the first example embodiment, so fM1>fT1.

As illustrated in FIG. 5C, in a case where the line length of the unbalanced line 310 is the second line length L4 (<first line length L3) and the unbalanced termination 312 of the unbalanced line 310 is in the ground state, the operation mode thereof is called MODE 3. A balun that operates in this operation mode is called a second line length transformer type balun. A center frequency of a frequency characteristic of the second line length transformer type balun (MODE 3) is set to fT2 as illustrated in FIG. 6A. As mentioned above, the second line length L4 is shorter than the first line length L3, so fT2>fT1.

Further, as illustrated in FIG. 5D, in a case where the line length of the unbalanced line 310 is the second line length L4 and the unbalanced termination 312 of the unbalanced line 310 is in the open state, the operation mode thereof is called MODE 4. A balun that operates in this operation mode is called a second line length Marchand balun. A center frequency of a frequency characteristic of the second line length Marchand balun (MODE 4) is set to fM2 as illustrated in FIG. 6A. As mentioned above, the second line length L4 is shorter than the first line length L3, so fM2>fM1.

FIG. 6B illustrates a state of a termination of the unbalanced line 310, a type of a balun in operation, a line length, and a center frequency (GHz) for each operation mode.

In each of the following example embodiments, the second line length L4 is determined so that the center frequency of each operation mode is to be fT1<fT2<fM1<fM2, as illustrated in FIG. 6A. As described above, the shorter the second line length L4 is, the higher the center frequency becomes. In the following example embodiments, fT2 and fM1 need only be different, for example, the second line length L4 may be determined so that fT1<fM1<fT2<fM2.

### Second Example Embodiment

Next, the second example embodiment to which the present disclosure is applied is described. In the present example embodiment, a type and line length conversion switch 410 is inserted in the middle of the unbalanced line 310 and the first balanced line 210 of the multiband balun 110 of the first example embodiment, respectively. These switches switch states of unbalanced terminations between the ground state and the open state. These switches also change line length of coupled lines. In the second example embodiment, the type and line length conversion switch 410 switches the operation mode of the multiband balun 120 between MODE 1 and MODE 4 described above. This enables the multiband balun 120 to support multiple band frequencies.

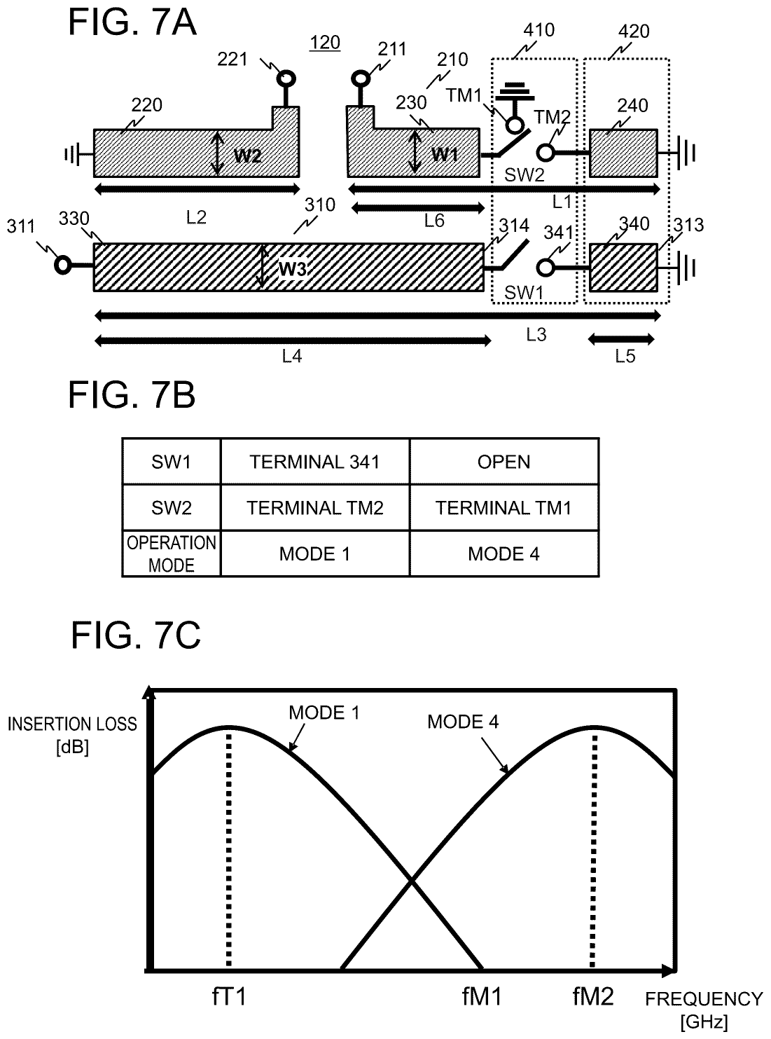

A schematic block diagram of the multiband balun 120 of the second example embodiment which realizes this is illustrated in FIG. 7A. In the present example embodiment, the configuration with the same name as the first example embodiment has basically the same function as the first example embodiment. The following description of the present example embodiment focuses on the points where it differs from the first example embodiment.

As illustrated in the drawing, the multiband balun 120 of the present example embodiment is provided with a first balanced line 210, a second balanced line 220, an unbalanced line 310, an unbalanced terminal 311, a first balanced terminal 211, a second balanced terminal 221, and a type and line length conversion switch 410.

Also, as well as the first example embodiment, one end of the first balanced line 210 is grounded and the other end thereof is connected to the first balanced terminal 211, which is connected to a balanced circuit. One end of the second balanced line 220 is grounded and the other end thereof is connected to the second balanced terminal 221, which is connected to the balanced circuit. A line length of the first balanced line 210 is L1. The first balanced line 210 is provided with a divided first balanced line 230 and a first adjustment line 240.

One end (first end) of the unbalanced line 310 is connected to the unbalanced terminal 311, which is connected to an unbalanced circuit. A line length of the unbalanced line 310 is a first line length L3. The unbalanced line 310 is provided with a divided unbalanced line 330 and a second adjustment line 340.

The type and line length conversion switch 410 is provided with a first switch SW1 and a second switch SW2.

The divided first balanced line 230 is a portion of line length L6 on a side, which is connected to the first balanced terminal 211, of the first balanced line 210. The one end of the divided first balanced line 230, opposite the side, which is connected to the first balanced terminal 211, is connected to the second switch SW2 of the type and line length conversion switch 410. In other words, the second switch SW2 is disposed by dividing the first balanced line 210.

The unbalanced line 310 of the present example embodiment is provided with a divided unbalanced line 330 and a second adjustment line 340. The divided unbalanced line 330 is a portion of the unbalanced line 310 that has a second line length L4, on a side connecting to the unbalanced terminal 311. A termination 314 (unbalanced termination), which is one end of the divided unbalanced line 330 opposite the one end connected to the unbalanced terminal 311, is connected to the first switch SW1 of the type and line length conversion switch 410. In other words, the first switch SW1 is disposed by dividing the unbalanced line 310.

In a case where there is no need to distinguish between the divided first balanced line 230 and the second balanced line 220, they are referred to as a balanced line. Likewise, in a case where there is no need to distinguish between the first adjustment line 240 and the second adjustment line 340, they are referred to as an adjustment line 420. Furthermore, in a case where there is no need to distinguish among the divided unbalanced line 330, the balanced line and the adjustment line 420, they are referred to as a coupled line.

In each of the following example embodiments, the controller is not shown in order to make the drawings easier to read. The function of the controller is the same as in the first example embodiment that it transmits a control signal to each switch and switches a state of the switches.

In the present example embodiment, as mentioned above, the first switch SW1 is disposed by dividing the unbalanced line 310 of the first example embodiment. Concretely, the first switch SW1 divides the unbalanced line 310 at line length L4 (L4<L3) from the end portion on the unbalanced terminal 311 side and is inserted at a termination 314 thereof, as illustrated in this drawing. In other words, the divided unbalanced line 330 is a portion of the unbalanced line 310, which is divided, on the unbalanced terminal 311 side, and the second adjustment line 340 is the other portion thereof. A line length L5 of the second adjustment line 340 satisfies L5=L3−L4.

The second switch SW2 is disposed by dividing the first balanced line 210 of the first example embodiment. In the present example embodiment, the first balanced line 210 is divided at line length L6 from the end portion on the first balanced terminal 211 side and the second switch SW2 is inserted thereof. In other words, the divided first balanced line 230 is a portion of the first balanced line 210, which is divided, on the first balanced terminal 211 side, and the first adjustment line 240 is the other portion thereof. A line length L5 of the first adjustment line 240 satisfies L5=L1−L6.

The second adjustment line 340 is provided with a terminal 341 on the first switch SW1 side. The termination 313 at an end portion opposite the terminal 341 is grounded.

The first adjustment line 240 has a terminal TM2 on the second switch SW2 side and an opposite end portion thereof is grounded.

The first switch SW1 operates according to a control signal from a controller and switches a state of the termination 314 between a state which is connected to a terminal 341 of the second adjustment line 340 and a state which is not connected to the terminal 341 (open state or open). This causes the first switch SW1 to change (switch) a state of a termination and a line length on the unbalanced line side.

The second switch SW2 operates according to a control signal from a controller and switches a line length of the divided first balanced line 230.

Sizes of the other parts of the multiband balun 120 of the present example embodiment are the same as those of the multiband balun 110 of the first example embodiment.

### [Operation]

The following describes each operation mode realized by an operation of the first switch SW1 and the second switch SW2 under the control of the controller. FIG. 7B illustrates an operation mode realized for each state of the first switch SW1 and the second switch SW2 of the multiband balun 120. FIG. 7C illustrates a frequency characteristic of the multiband balun 120 at each operation mode.

If the first switch SW1 is connected to the terminal 341, the divided unbalanced line 330 and the second adjustment line 340 are connected. The second switch SW2 is connected to the terminal TM2. In this case, a total line length of the unbalanced line is L3 (first line length) and an unbalanced termination 312 (see FIG. 5A to FIG. 5D, the same applies hereinafter) is the termination 313 of the second adjustment line 340. The termination 313 thereof is in a ground state. Therefore, the multiband balun 120 operates as a transformer type balun whose line length is the first line length. In other words, the multiband balun 120 operates in MODE 1 as described above. The center frequency thereof is fT1, as illustrated in FIG. 7C.

On the other hand, in a case where the first switch SW1 is in the open state, the divided unbalanced line 330 is not connected to the second adjustment line 340. In this case, the second switch SW2 is connected to the terminal TM1. In this case, a line length of the unbalanced line is L4 (second line length) and an unbalanced termination 312 is the termination 314 of the divided unbalanced line 330. The termination 314 thereof is in the open state. Therefore, the multiband balun 120 operates as a Marchand balun whose line length is the second line length. In other words, the multiband balun 120 operates in MODE 4 as described above. The center frequency thereof is fM2, as illustrated in FIG. 7C.

As explained above, the multiband balun 120 of the present example embodiment is provided with the type and line length conversion switch 410. The type and line length conversion switch 410 can switch the state of the unbalanced termination on the unbalanced line side between the open state and the ground state, and can switch the line length on the unbalanced line side between the first line length, which is a line length at an initial design, and the second line length, which is shorter than the first line length. By switching the type and line length conversion switch 410 according to the control signal from the controller, the multiband balun 120 can be operated as one of a transformer type balun with a first line length and a Marchand balun with a second line length which is shorter than the first line length (short line length Marchand balun).

As mentioned above, their center frequencies fT1 and fM2 are different. Therefore, the multiband balun 120 of the present example embodiment can change the center frequency thereof by switching the type and line length conversion switch 410 with the control signal from the controller. In other words, the multiband balun 120 can support two different pass band frequencies.

In addition, the multiband balun 120 of the present example embodiment only adds the type and line length conversion switch 410 at a location where the unbalanced line 310 and the first balanced line 210 are divided, as a circuit configuration. Therefore, the multiband balun 120 does not increase a circuit area. Thus, according to the present example embodiment, a multiband balun with a small area and variable bandwidth can be realized.

### Third Example Embodiment

Next, the third example embodiment to which the present disclosure is applied is described. In the present example embodiment, as well as the second example embodiment, a type and line length conversion switch 410 is inserted in the middle of the unbalanced line 310 and the first balanced line 210 of the multiband balun 110 of the first example embodiment, respectively. These switches switch states of unbalanced terminations between the ground state and the open state. These switches also change line length of coupled lines. In the present example embodiment, the type and line length conversion switch 410 switches the operation mode of the multiband balun 130 between MODE 3 and MODE 2 described above. This enables the multiband balun 130 to support multiple band frequencies.

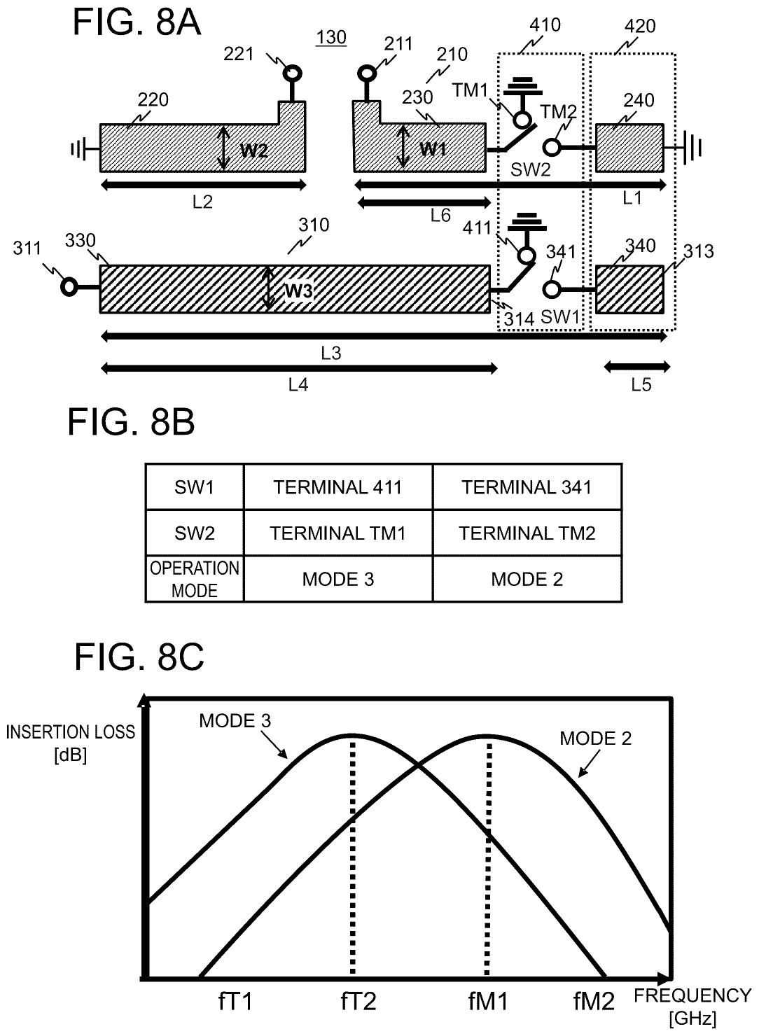

A schematic block diagram of the multiband balun 130 of the present example embodiment which realizes this is illustrated in FIG. 8A. In the present example embodiment, the configuration with the same name as the first example embodiment has basically the same function as the first example embodiment. The following description of the present example embodiment focuses on the points where it differs from the first example embodiment.

As illustrated in the drawing, the multiband balun 130 of the present example embodiment is provided with a first balanced line 210, a second balanced line 220, an unbalanced line 310, an unbalanced terminal 311, a first balanced terminal 211, a second balanced terminal 221, and a type and line length conversion switch 410.

Also, as well as the first example embodiment, one end of the first balanced line 210 is grounded and the other end (second end) thereof is connected to the first balanced terminal 211, which is connected to a balanced circuit. One end of the second balanced line 220 is grounded and the other end thereof is connected to the second balanced terminal 221, which is connected to the balanced circuit. A line length of the first balanced line 210 is L1. The first balanced line 210 is provided with a divided first balanced line 230 and a first adjustment line 240.

One end (first end) of the unbalanced line 310 is connected to the unbalanced terminal 311, which is connected to an unbalanced circuit. A line length of the unbalanced line 310 is a first line length L3. The unbalanced line 310 is provided with a divided unbalanced line 330 and a second adjustment line 340.

The type and line length conversion switch 410 is provided with a first switch SW1 and a second switch SW2.

The divided first balanced line 230 is a portion of the first balanced line 210 that has a line length L6, on a side connecting to the first balanced terminal 211. The one end of the divided first balanced line 230, opposite the side, which is connected to the first balanced terminal 211, is connected to the second switch SW2 of the type and line length conversion switch 410. In other words, the second switch SW2 is disposed by dividing the first balanced line 210.

The unbalanced line 310 of the present example embodiment is provided with a divided unbalanced line 330 and a second adjustment line 340. The divided unbalanced line 330 is a portion of the unbalanced line 310 that has a second line length L4, on a side connecting to the unbalanced terminal 311. A termination 314, which is one end of the divided unbalanced line 330 opposite the one end connected to the unbalanced terminal 311, is connected to the first switch SW1 of the type and line length conversion switch 410. In other words, the first switch SW1 is disposed by dividing the unbalanced line 310.

The size, position, etc. of each part are basically the same as a configuration of the same name in the second example embodiment. However, the termination 313, which is an end portion of the second adjustment line 340 of the present example embodiment, is in an open state. The first switch SW1 is provided with a terminal 411 grounded.

The first switch SW1 operates according to a control signal from a controller and switches a state of the termination 313 between a state which is connected to a terminal 341 of the second adjustment line 340 and a state which is connected to the terminal 411 to be grounded. This causes the first switch SW1 to change a state of a termination and a line length on the unbalanced line side. In other words, the first switch SW1 switches the line length on the unbalanced line side between the first line length L1 and the second line length L2, and the termination state thereof between the open state and the ground state.

### [Operation]

The following describes each operation mode realized by an operation of the first switch SW1 and the second switch SW2 under the control of the controller. FIG. 8B illustrates an operation mode realized for each state of the first switch SW1 and the second switch SW2 of the multiband balun 130. FIG. 8C illustrates a frequency characteristic of the multiband balun 130 at each operation mode.

If the first switch SW1 is connected to the terminal 341, the divided unbalanced line 330 and the second adjustment line 340 are connected. The second switch SW2 is connected to the terminal TM2. In this case, a total line length of the unbalanced line is L3 (first line length) and the unbalanced termination 312 is the termination 313 of the second adjustment line 340. The termination 313 thereof is in the ground state. Therefore, the multiband balun 130 operates as a Marchand balun whose line length is the first line length. In other words, the multiband balun 130 operates in MODE 2 as described above. The center frequency thereof is fM1, as illustrated in FIG. 8C.

On the other hand, in a case where the first switch SW1 is connected to the terminal 411, the divided unbalanced line 330 is not connected to the second adjustment line 340. In this case, the second switch SW2 is connected to the terminal TM1. In this case, a line length of the unbalanced line is L4 (second line length) and the unbalanced termination 312 is the termination 314 of the divided unbalanced line 330. The termination 314 thereof is in the ground state. Therefore, the multiband balun 130 operates as a transformer type balun whose line length is the second line length. In other words, the multiband balun 130 operates in MODE 3 as described above. The center frequency thereof is fT2, as illustrated in FIG. 8C.

As explained above, the multiband balun 130 of the present example embodiment can be operated as one of a Marchand balun with a first line length and a transformer type balun with a second line length which is shorter than the first line length by means of the type and line length conversion switch 410.

As mentioned above, their center frequencies fT2 and fM1 are different. Therefore, the multiband balun 130 of the present example embodiment can change the center frequency thereof by switching the type and line length conversion switch 410 with the control signal from the controller. In other words, the multiband balun 130 can support two different pass band frequencies.

In addition, the multiband balun 130 of the present example embodiment only adds the type and line length conversion switch 410 at a location where the unbalanced line 310 and the first balanced line 210 are divided, as a circuit configuration. Therefore, the multiband balun 120 does not increase a circuit area. Thus, according to the present example embodiment, a multiband balun with a small area and variable bandwidth can be realized.

### Fourth Example Embodiment

Next, the fourth example embodiment to which the present disclosure is applied is described. In the present example embodiment, a multiband balun 140 that can support three different bands is realized by adding a terminal 411 to the first switch SW1 of the second example embodiment. The terminal 411 is a terminal of a ground state with respect to a high frequency signal.

The following description of the present example embodiment focuses on the points where it differs from the first example embodiment.

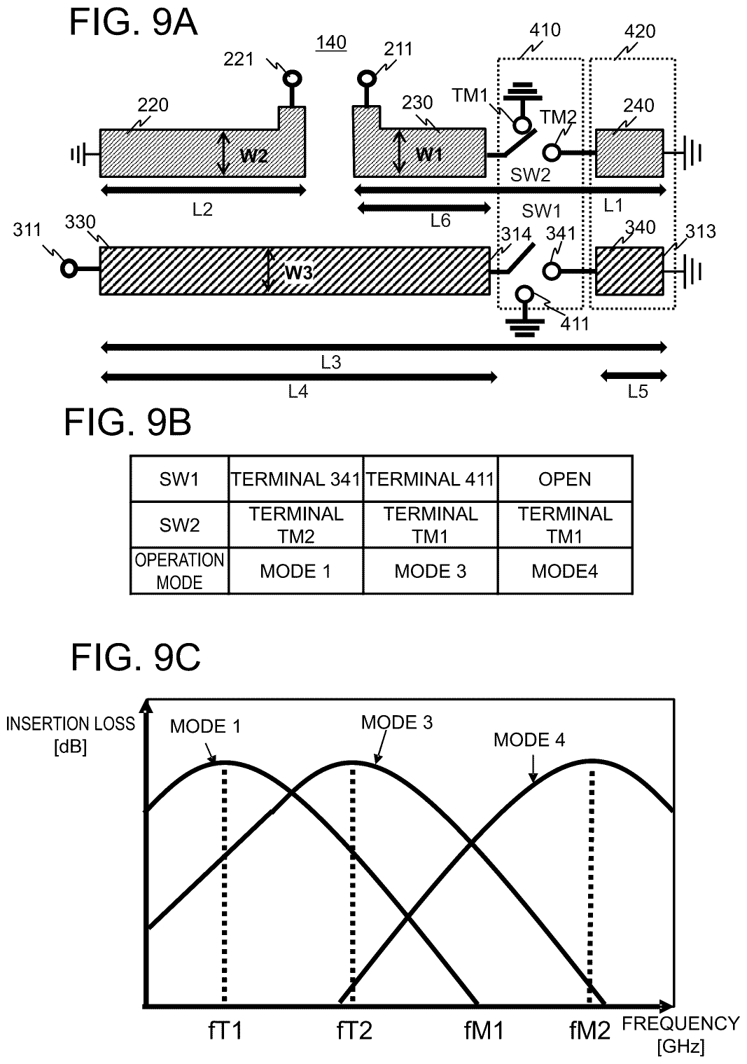

FIG. 9A is a schematic block diagram of a multiband balun 140 of the present example embodiment. As illustrated in the diagram, the multiband balun 140 of the present example embodiment is provided with the same configuration as the multiband balun 120 of the second example embodiment.

However, as mentioned above, the first switch SW1 of the present example embodiment is further provided with a terminal 411 whose termination is in a ground state. Therefore, the first switch SW1 can switch a state of the termination 313 among a state connected to the terminal 341, a state connected to the terminal 411 in a ground state, and an open state, according to a control signal from a controller. In other words, the termination 313 can take three states.

### [Operation]

The following describes each operation mode realized by an operation of the first switch SW1 and the second switch SW2 under the control of the controller. FIG. 9B illustrates an operation mode realized for each state of the first switch SW1 and the second switch SW2 of the multiband balun 140. FIG. 9C illustrates a frequency characteristic of the multiband balun 140 at each operation mode.

If the first switch SW1 is connected to the terminal 341, the divided unbalanced line 330 and the second adjustment line 340 are connected. The second switch SW2 is connected to the terminal TM2. In this case, a total line length of the unbalanced line is L3 (first line length) and the termination 313 thereof is in a ground state. Therefore, the multiband balun 140 operates as a transformer type balun whose line length is the first line length. In other words, the multiband balun 140 operates in MODE 1 as described above. The center frequency thereof is fT1, as illustrated in FIG. 9C.

In a case where the first switch SW1 is in the open state, the divided unbalanced line 330 is not connected to the second adjustment line 340. In this case, the second switch SW2 is connected to the terminal TM1. In this case, a line length of the unbalanced line is L4 (second line length) and the termination 314 thereof is in an open state. Therefore, the multiband balun 140 operates as a Marchand balun whose line length is the second line length. In other words, the multiband balun 140 operates in MODE 4 as described above. The center frequency thereof is fM2, as illustrated in FIG. 9C.

Furthermore, if the first switch SW1 is connected to the terminal 411 in the ground state, the divided unbalanced line 330 is not connected to the second adjustment line 340. In this case, the second switch SW2 is connected to the terminal TM1. In this case, a line length of the unbalanced line is L4 (second line length) and the termination 314 thereof is in a ground state. Therefore, the multiband balun 140 operates as a transformer type balun whose line length is the second line length. In other words, the multiband balun 140 operates in MODE 3 as described above. The center frequency thereof is fT2, as illustrated in FIG. 9C.

As explained above, the multiband balun 140 of the present example embodiment can be operated as one of a transformer type balun with a first line length, a Marchand balun with a second line length, and a transformer type balun with a second line length by means of the type and line length conversion switch 410.

As mentioned above, their center frequencies fT1, fT2 and fM2 are different. Therefore, the multiband balun 140 of the present example embodiment can change the center frequency thereof by switching the type and line length conversion switch 410 with the control signal from the controller. In other words, the multiband balun 140 can support three different pass band frequencies.

In addition, the multiband balun 140 of the present example embodiment only adds the type and line length conversion switch 410 at a location where the unbalanced line 310 and the first balanced line 210 are divided, as a circuit configuration. Therefore, the multiband balun 140 does not increase a circuit area. Thus, according to the present example embodiment, a multiband balun with a small area and variable bandwidth can be realized.

### Fifth Example Embodiment

Next, the fifth example embodiment to which the present disclosure is applied is described. In the present example embodiment, a pattern is added to the first switch SW1 of the third example embodiment. The pattern added is one that switches a state of the termination 314 of the divided unbalanced line 330 to an open state with respect to a high frequency signal. Thus, a multiband balun 150 that can support three different bands is realized.

The following description of the present example embodiment focuses on the points where it differs from the third example embodiment.

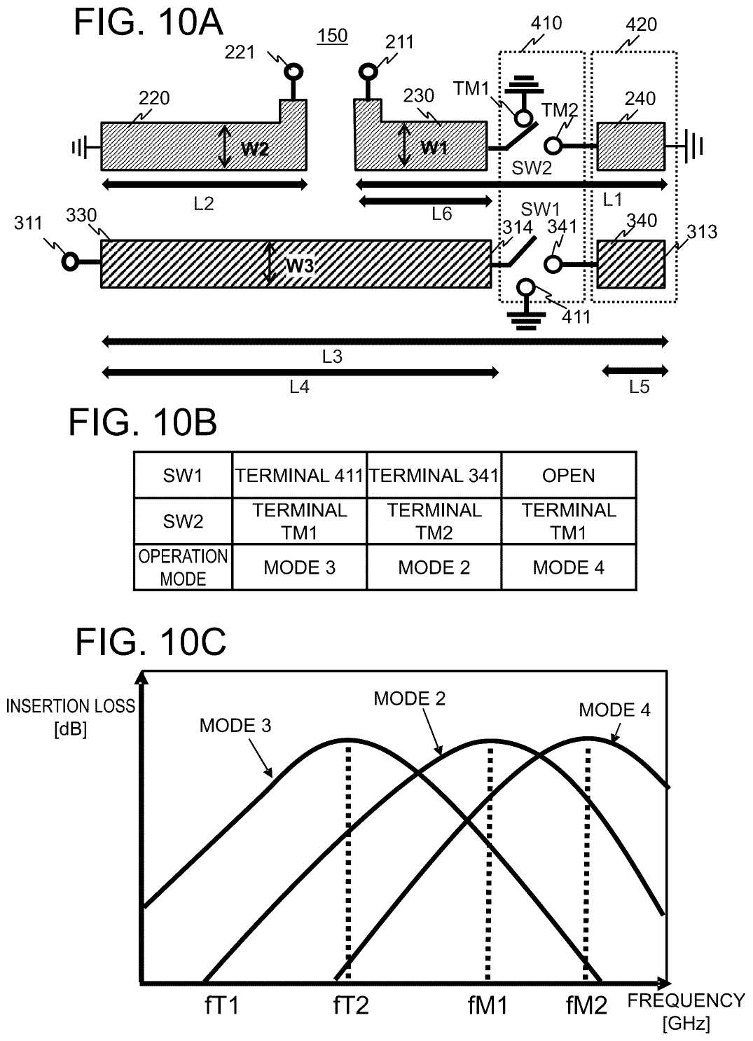

FIG. 10A is a schematic block diagram of a multiband balun 150 of the present example embodiment. As illustrated in the diagram, the multiband balun 150 of the present example embodiment is provided with the same configuration as the multiband balun 130 of the third example embodiment.

However, as mentioned above, the first switch SW1 of the present example embodiment can further make the termination 314 thereof in an open state (open). Therefore, the first switch SW1 can switch a state of the termination 314 among a state connected to the terminal 341, a state connected to the terminal 411 in the ground state, and an open state, according to a control signal from a controller. In other words, the termination 314 can take three states.

### [Operation]

The following describes each operation mode realized by an operation of the first switch SW1 and the second switch SW2 under the control of the controller. FIG. 10B illustrates an operation mode realized for each state of the first switch SW1 and the second switch SW2 of the multiband balun 150. FIG. 10C illustrates a frequency characteristic of the multiband balun 150 at each operation mode.

If the first switch SW1 is connected to the terminal 341, the divided unbalanced line 330 and the second adjustment line 340 are connected. The second switch SW2 is connected to the terminal TM2. In this case, a total line length of the unbalanced line is L3 (first line length) and the termination 313 thereof is in an open state. Therefore, the multiband balun 150 operates as a Marchand balun whose line length is the first line length. In other words, the multiband balun 150 operates in MODE 2 as described above. The center frequency thereof is fM1, as illustrated in FIG. 10C.

In a case where the first switch SW1 is connected to the terminal 411, the divided unbalanced line 330 is not connected to the second adjustment line 340. In this case, the second switch SW2 is connected to the terminal TM1. In this case, a line length of the unbalanced line is L4 (second line length) and the termination 314 thereof is in a ground state. Therefore, the multiband balun 150 operates as a transformer type balun whose line length is the second line length. In other words, the multiband balun 150 operates in MODE 3 as described above. The center frequency thereof is fT2, as illustrated in FIG. 10C.

Furthermore, in a case where the first switch SW1 is in an open state, the divided unbalanced line 330 is not connected to the second adjustment line 340. In this case, the second switch SW2 is connected to the terminal TM1. In this case, a line length of the unbalanced line is L4 (second line length) and the termination 314 thereof is in an open state. Therefore, the multiband balun 150 operates as a Marchand balun whose line length is the second line length. In other words, the multiband balun 150 operates in MODE 4 as described above. The center frequency thereof is fM2, as illustrated in FIG. 10C.

As explained above, the multiband balun 150 of the present example embodiment can be operated as one of a Marchand balun with a first line length, a transformer type balun with a second line length, and a Marchand balun with a second line length by means of the type and line length conversion switch 410.

As mentioned above, their center frequencies fT2, fM1 and fM2 are different. Therefore, the multiband balun 150 of the present example embodiment can change the center frequency thereof by switching the type and line length conversion switch 410 with the control signal from the controller. In other words, the multiband balun 150 can support three different pass band frequencies.

In addition, the multiband balun 150 of the present example embodiment only adds the type and line length conversion switch 410 at a location where the unbalanced line 310 and the first balanced line 210 are divided, as a circuit configuration. Therefore, the multiband balun 150 does not increase a circuit area. Thus, according to the present example embodiment, a multiband balun with a small area and variable bandwidth can be realized.

### Sixth Example Embodiment

Next, the sixth example embodiment to which the present disclosure is applied is described. In the present example embodiment, a second type conversion switch 430 is disposed at a termination 313 of the second adjustment line 340 of the second example embodiment. The second type conversion switch 430 is a switch that can switch a state of the termination 313 thereof between an open state and a ground state with respect to the high frequency signal. Thus, in the present example embodiment, a multiband balun 160 that can support three different bands is realized.

The following description of the present example embodiment focuses on the points where it differs from the second example embodiment.

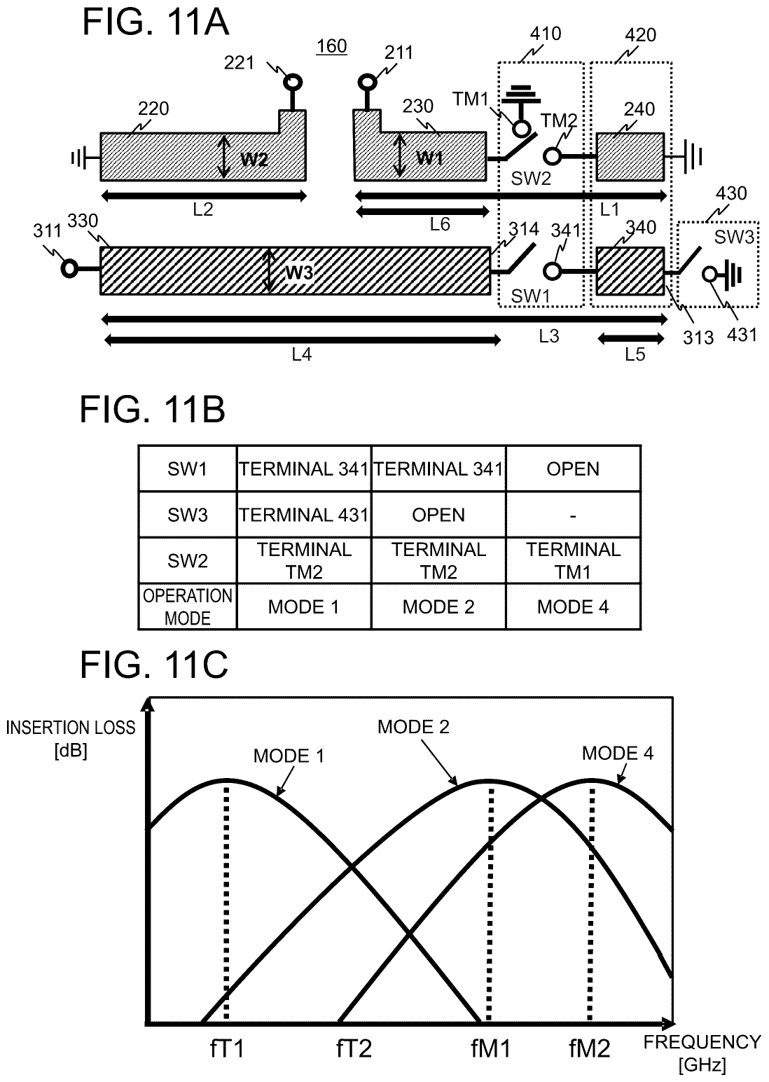

FIG. 11A is a schematic block diagram of a multiband balun 160 of the present example embodiment. As illustrated in the diagram, the multiband balun 160 of the present example embodiment is provided with the same configuration as the multiband balun 120 of the second example embodiment. However, as mentioned above, it is further provided with a second type conversion switch 430 at a termination 313 of the second adjustment line 340.

The second type conversion switch 430 is provided with a third switch SW3 that can switch a state of the termination 313 between a ground state and an open state according to a control signal from a controller. The third switch SW3 is provided with a terminal 431 whose termination is in a ground state.

### [Operation]

The following describes each operation mode realized by an operation of the first switch SW1, the second switch SW2, and the third switch SW3 under the control of the controller. FIG. 11B illustrates an operation mode realized for each state of the first switch SW1, the second switch SW2, and the third switch SW3 of the multiband balun 160. FIG. 11C illustrates a frequency characteristic of the multiband balun 160 at each operation mode.

If the first switch SW1 is connected to the terminal 341, the divided unbalanced line 330 and the second adjustment line 340 are connected. The second switch SW2 is connected to the terminal TM2. In this case, a total line length of the unbalanced line is L3 (first line length). If the third switch SW3 is connected to the terminal 431, a termination of the unbalanced line is to be a ground state. Therefore, the multiband balun 160 operates as a transformer type balun whose line length is the first line length. In other words, the multiband balun 160 operates in MODE 1 as described above. The center frequency thereof is fT1, as illustrated in FIG. 11C.

In a case where the third switch SW3 is in an open state (open) under a condition where the first switch SW1 is connected to the terminal 341 and the second switch SW2 is connected to the terminal TM2, a line length of the unbalanced line is to be L3 (first line length) and a termination thereof is to be an open state. Therefore, the multiband balun 160 operates as a Marchand balun whose line length is the first line length. In other words, the multiband balun 160 operates in MODE 2 as described above. The center frequency thereof is fM1, as illustrated in FIG. 11C.

On the other hand, if the first switch SW1 is in an open state, the divided unbalanced line 330 is not connected to the second adjustment line 340. In this case, the second switch SW2 is connected to the terminal TM1. In this case, a line length of the unbalanced line is L4 (second line length) and the termination 314 thereof is in an open state. Therefore, the multiband balun 160 operates as a Marchand balun whose line length is the second line length. In other words, the multiband balun 160 operates in MODE 4 as described above. The center frequency thereof is fM2, as illustrated in FIG. 11C.

As explained above, the multiband balun 160 of the present example embodiment can be operated as one of a transformer type balun with a first line length, a Marchand balun with a first line length, and a Marchand balun with a second line length by means of the type and line length conversion switch 410 and the second type conversion switch 430.

As mentioned above, their center frequencies fT1, fM1 and fM2 are different. Therefore, the multiband balun 160 of the present example embodiment can change the center frequency thereof by switching the type and line length conversion switch 410 and the second type conversion switch 430 with the control signal from the controller. In other words, the multiband balun 160 can support three different pass band frequencies.

In addition, the multiband balun 160 of the present example embodiment only adds the type and line length conversion switch 410 and the second type conversion switch 430, as a circuit configuration. Therefore, the multiband balun 160 does not increase a circuit area. Thus, according to the present example embodiment, a multiband balun with a small area and variable bandwidth can be realized.

### Seventh Example Embodiment

Next, the seventh example embodiment to which the present disclosure is applied is described. In the present example embodiment, a second type conversion switch 430 is disposed at a termination 313 of the second adjustment line 340 of the third example embodiment at 313. The second type conversion switch 430 is a switch that can switch a state of the termination 313 between an open state and a ground state with respect to the high frequency signal. Thus, in the present example embodiment, a multiband balun 170 that can support three different bands is realized.

The following description of the present example embodiment focuses on the points where it differs from the third example embodiment.

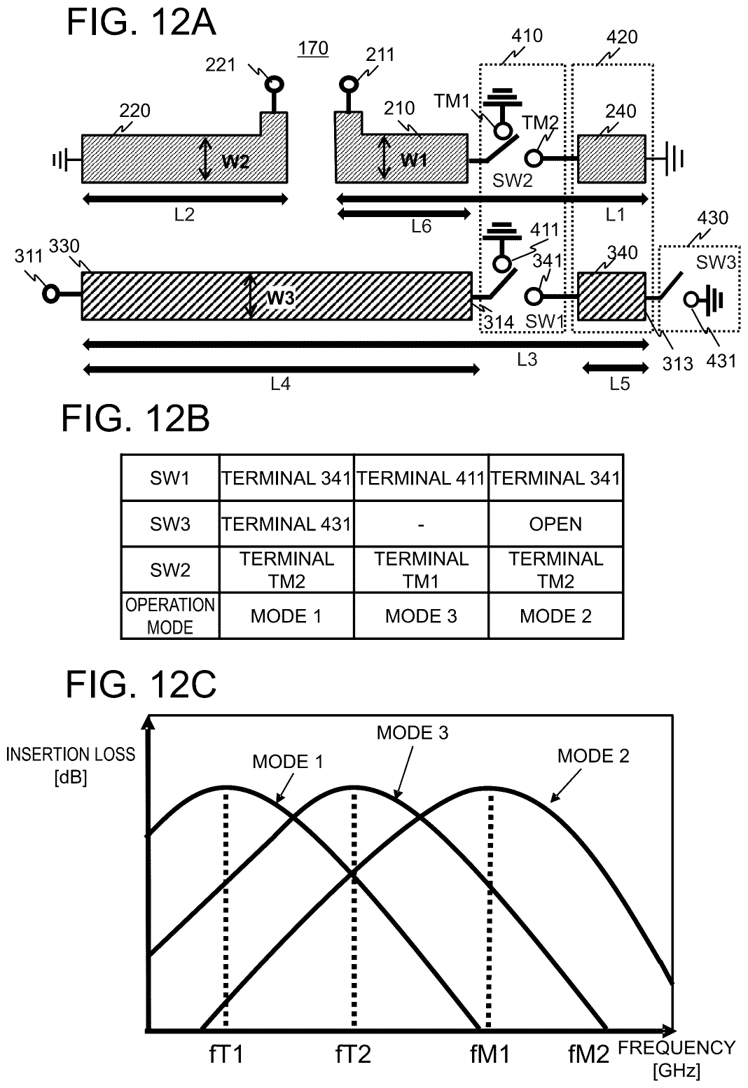

FIG. 12A is a schematic block diagram of a multiband balun 170 of the present example embodiment. As illustrated in the diagram, the multiband balun 170 of the present example embodiment is provided with the same configuration as the multiband balun 130 of the third example embodiment. However, as mentioned above, it is further provided with a second type conversion switch 430 at a termination 313 of the second adjustment line 340.

The second type conversion switch 430 is provided with a third switch SW3 that can switch a state of the termination 313 between a ground state and an open state according to a control signal from a controller. The third switch SW3 is provided with a terminal 431 whose termination is in a ground state.

### [Operation]

The following describes each operation mode realized by an operation of the first switch SW1, the second switch SW2, and the third switch SW3 under the control of the controller. FIG. 12B illustrates an operation mode realized for each state of the first switch SW1, the second switch SW2, and the third switch SW3 of the multiband balun 170. FIG. 12C illustrates a frequency characteristic of the multiband balun 170 at each operation mode.

If the first switch SW1 is connected to the terminal 341, the divided unbalanced line 330 and the second adjustment line 340 are connected. The second switch SW2 is connected to the terminal TM2. In this case, a total line length of the unbalanced line is L3 (first line length). If the third switch SW3 is connected to the terminal 431, a termination of the unbalanced line is to be a ground state. Therefore, the multiband balun 170 operates as a transformer type balun whose line length is the first line length. In other words, the multiband balun 170 operates in MODE 1 as described above. The center frequency thereof is fT1, as illustrated in FIG. 12C.

In a case where the third switch SW3 is in an open state (open) under a condition where the first switch SW1 is connected to the terminal 341 and the second switch SW2 is connected to the terminal TM2, a line length of the unbalanced line is to be L3 (first line length) and a termination thereof is to be an open state. Therefore, the multiband balun 170 operates as a Marchand balun whose line length is the first line length. In other words, the multiband balun 170 operates in MODE 2 as described above. The center frequency thereof is fM1, as illustrated in FIG. 12C.

On the other hand, if the first switch SW1 is connected to the terminal 411, the divided unbalanced line 330 is not connected to the second adjustment line 340. In this case, the second switch SW2 is connected to the terminal TM1. In this case, a line length of the unbalanced line is L4 (second line length) and the termination 314 thereof is in a ground state. Therefore, the multiband balun 170 operates as a transformer type balun whose line length is the second line length. In other words, the multiband balun 170 operates in MODE 3 as described above. The center frequency thereof is fT2, as illustrated in FIG. 12C.

As explained above, the multiband balun 170 of the present example embodiment can be operated as one of a transformer type balun with a first line length, a Marchand balun with a first line length, and a transformer type balun with a second line length by means of the type and line length conversion switch 410 and the second type conversion switch 430.

As mentioned above, their center frequencies fT1, fT2 and fM1 are different. Therefore, the multiband balun 170 of the present example embodiment can change the center frequency thereof by switching the type and line length conversion switch 410 and the second type conversion switch 430 with the control signal from the controller. In other words, the multiband balun 170 can support three different pass band frequencies.

In addition, the multiband balun 170 of the present example embodiment only adds the type and line length conversion switch 410 and the second type conversion switch 430, as a circuit configuration. Therefore, the multiband balun 170 does not increase a circuit area.

Thus, according to the present example embodiment, a multiband balun with a small area and variable bandwidth can be realized.

### Eighth Example Embodiment

Next, the eighth example embodiment to which the present disclosure is applied is described. In the present example embodiment, a pattern is added to the first switch SW1 of the seventh example embodiment. The pattern added is one that switches a state of the termination 314 of the divided unbalanced line 330 to an open state with respect to a high frequency signal. Thus, in a present embodiment, a multiband balun 180 that can support four different bands is realized.

The following description of the present example embodiment focuses on the points where it differs from the seventh example embodiment.

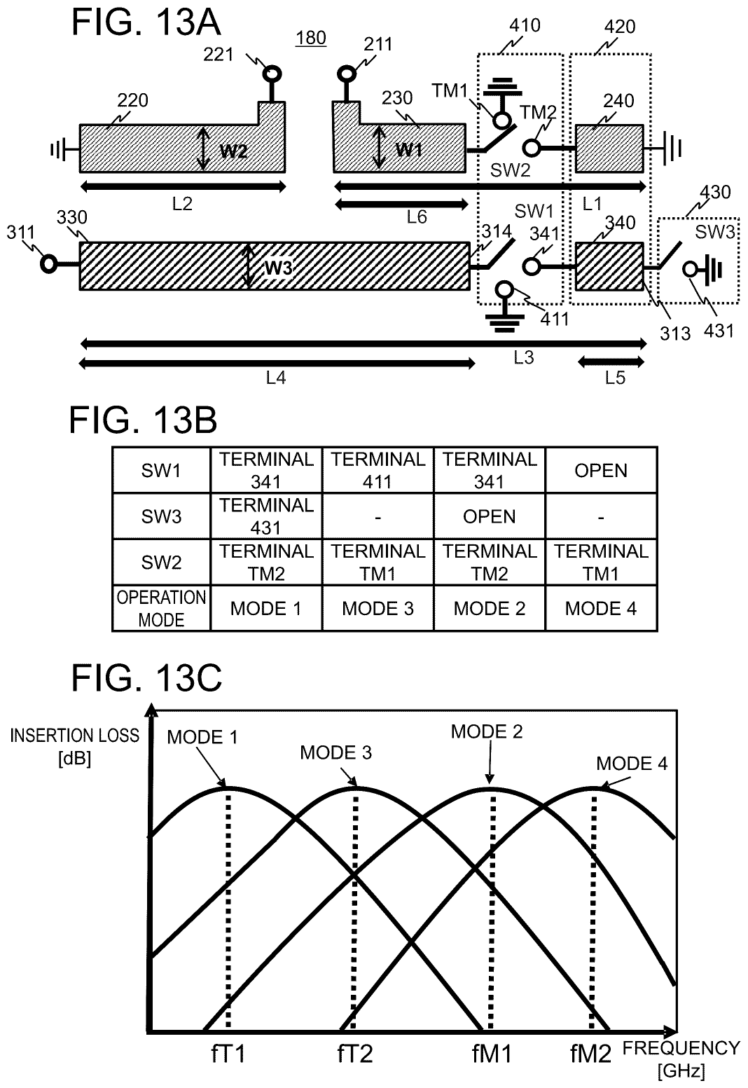

FIG. 13A is a schematic block diagram of a multiband balun 180 of the present example embodiment. As illustrated in the diagram, the multiband balun 180 of the present example embodiment is provided with the same configuration as the multiband balun 170 of the seventh example embodiment. Furthermore, as mentioned above, the multiband balun 180 can make the termination 314 thereof in an open state (open). Therefore, the first switch SW1 can switch a state of the termination 314 among a state connected to the terminal 341, a state connected to the terminal 411 in the ground state, and an open state, according to a control signal from a controller. In other words, the termination 314 can take three states.

The second type conversion switch 430 is provided with a third switch SW3 that can switch a state of the termination 313 between a ground state and an open state according to a control signal from a controller. The third switch SW3 is provided with a terminal 431 whose termination is in a ground state.

Therefore, when the first switch SW1 is connected to terminal 341, the state of the termination 313 can be switched by the third switch SW3 between a state connected to the terminal 431 in the ground state and the open state.

### [Operation]

The following describes each operation mode realized by an operation of the first switch SW1, the second switch SW2, and the third switch SW3 under the control of the controller. FIG. 13B illustrates an operation mode realized for each state of the first switch SW1, the second switch SW2, and the third switch SW3 of the multiband balun 180. FIG. 13C illustrates a frequency characteristic of the multiband balun 180 at each operation mode.

If the first switch SW1 is connected to the terminal 341, the divided unbalanced line 330 and the second adjustment line 340 are connected. The second switch SW2 is connected to the terminal TM2. In this case, a total line length of the unbalanced line is L3 (first line length). If the third switch SW3 is connected to the terminal 431, a termination of the unbalanced line is to be a ground state. Therefore, the multiband balun 180 operates as a transformer type balun whose line length is the first line length. In other words, the multiband balun 180 operates in MODE 1 as described above. The center frequency thereof is fT1, as illustrated in FIG. 13C.

In a case where the third switch SW3 is in an open state (open) under a condition where the first switch SW1 is connected to the terminal 341 and the second switch SW2 is connected to the terminal TM2, the unbalanced line has a line length of L3 (first line length) and a termination thereof is to be an open state. Therefore, the multiband balun 180 operates as a Marchand balun whose line length is the first line length. In other words, the multiband balun 180 operates in MODE 2 as described above. The center frequency thereof is fM1, as illustrated in FIG. 13C.

If the first switch SW1 is connected to the terminal 411, the divided unbalanced line 330 is not connected to the second adjustment line 340. In this case, the second switch SW2 is connected to the terminal TM1. In this case, a line length of the unbalanced line is L4 (second line length) and the termination 314 thereof is in a ground state. Therefore, the multiband balun 180 operates as a transformer type balun whose line length is the second line length. In other words, the multiband balun 180 operates in MODE 3 as described above. The center frequency thereof is fT2, as illustrated in FIG. 13C.

Furthermore, if the first switch SW1 is in an open state, the divided unbalanced line 330 is not connected to the second adjustment line 340. In this case, the second switch SW2 is connected to the terminal TM1. In this case, a line length of the unbalanced line is L4 (second line length) and the termination 314 thereof is in an open state. Therefore, the multiband balun 180 operates as a Marchand balun whose line length is the second line length. In other words, the multiband balun 180 operates in MODE 4 as described above. The center frequency thereof is fM2, as illustrated in FIG. 13C.

As explained above, the multiband balun 180 of the present example embodiment can be operated as one of a transformer type balun with a first line length, a Marchand balun with a first line length, a transformer type balun with a second line length, and a Marchand balun with a second line length by means of the type and line length conversion switch 410 and the second type conversion switch 430.

As mentioned above, their center frequencies fT1, fT2, fM1 and fM2 are different. Therefore, the multiband balun 180 of the present example embodiment can change the center frequency thereof by switching the type and line length conversion switch 410 and the second type conversion switch 430 with the control signal from the controller. In other words, the multiband balun 180 can support four different pass band frequencies.

In addition, the multiband balun 180 of the present example embodiment only adds the type and line length conversion switch 410 and the second type conversion switch 430, as a circuit configuration. Therefore, the multiband balun 180 does not increase a circuit area. Thus, according to the present example embodiment, a multiband balun with a small area and variable bandwidth can be realized.

### Variation Example 1

In each of the above example embodiments, each switch (a first switch SW1, a second switch SW2, and a third switch SW3) is explained using a case in which, for example, a FET 402, which can be switched by an applied voltage, is used. However, the configuration to realize each switch is not limited to this. As long as it is possible to switch among two or three states, there are no restrictions. For example, each switch may be a PIN diode, etc. Current-driven transistors may be used for each switch.

### Variation Example 2

For simplicity of explanation, an upper layer metal and a lower layer metal of the multiband balun are specified in each of the above sample embodiments, but a structure thereof is not limited to these. The structure thereof can be such that it can be coupled.

### Variation Example 3

In each of the above example embodiments, the balanced line side is divided from the first balanced line side and the second switch SW2 is inserted to adjust the line length, but is not limited to this. For example, a line length may be adjusted by inserting a second switch SW2 on the second balanced line side. The line length may be adjusted by inserting second switches SW2s on both the first balanced line and the second balanced line.

### Variation Example 4

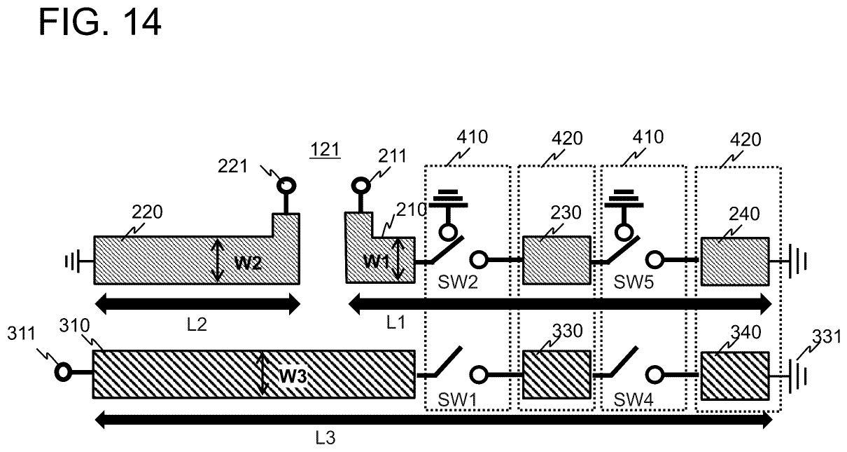

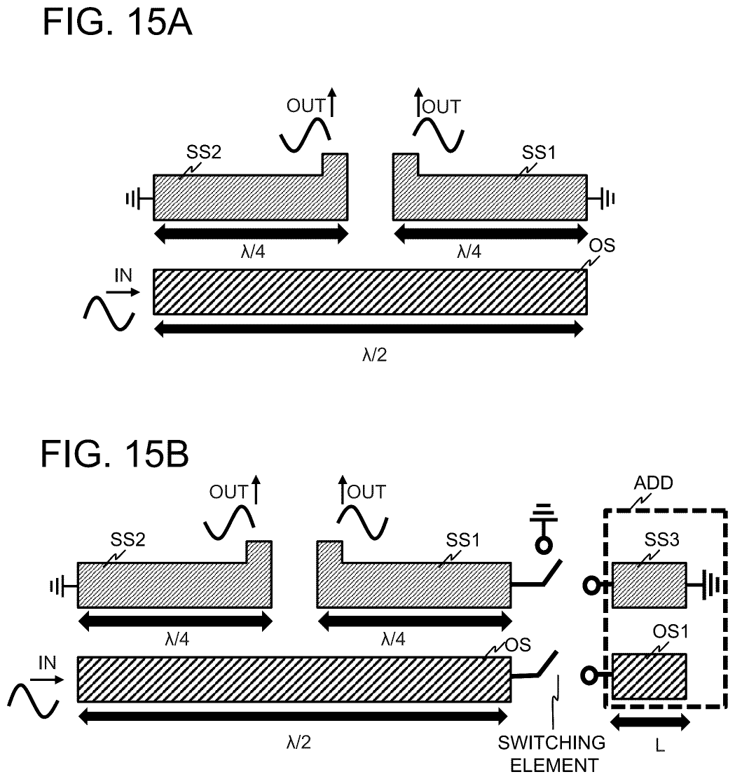

In each of the above example embodiments, the unbalanced line 310 and the first balanced line 210 are each divided at one location, and the type and line length conversion switch 410 is inserted to adjust the line length. However, it is not limited to this. For example, as illustrated in FIG. 14, multiple locations may be divided and the type and line length conversion switch 410 may be inserted at each division point. Here, an example based on the second example embodiment above is illustrated. The same applies to other example embodiments. This allows the line length of each coupled line to be adjusted in various ways, thereby increasing the number of frequency bands that can be supported.

Although the present disclosure has been described with reference to the example embodiments and variation examples, the present disclosure is not limited thereto. Various modifications that can be understood by those skilled in the art can be made to the configurations and details of the present invention within the scope of the present invention. Each example embodiment and variation example can be combined with other example embodiments and/or variation examples as appropriate. Note that the network configuration and the configuration of each element illustrated in each drawing are examples to promote better understanding of the present disclosure and are not limited to the configurations illustrated in these drawings.

Finally, preferred modes of the present disclosure will be summarized. The whole or part of example embodiments disclosed above can be described as, but not limited thereto, the following Supplementary Notes.

### (Supplementary Note 1)

A multiband balun includes:
a first balanced line, one end of the first balanced line being grounded and an other end of the first balanced line being connected to a balanced terminal, the balanced terminal being connected to a balanced circuit;
a second balanced line, one end of the second balanced line being grounded and an other end of the second balanced line being connected to a balanced terminal, the balanced terminal being connected to the balanced circuit;
an unbalanced line, one end of the unbalanced line being connected to an unbalanced terminal, the unbalanced terminal being connected to an unbalanced circuit; and
a first switch, wherein
the first switch switches a state of an unbalanced termination to one of an open state and a ground state, the unbalanced termination being one end of the unbalanced line opposite the one end connected to the unbalanced terminal.

### (Supplementary Note 2)

In the multiband balun described in the supplementary note 1, it is preferable that the unbalanced line has a first line length, and the first switch further switches a line length of the unbalanced line to one of the first line length and a second line length, the second line length being shorter than the first line length.

### (Supplementary Note 3)

In the multiband balun described in supplementary note 2, it is preferable that
the unbalanced line includes a divided unbalanced line and an adjustment line, the divided unbalanced line being a portion of a side that connects to the unbalanced terminal and having the second line length shorter than the first line length, the adjustment line having a length less than or equal to a difference between the first line length and the second line length,
one end of the adjustment line of the divided unbalanced line side is connected to a first terminal and an other end of the adjustment line is grounded, and
the first switch switches a state of the unbalanced termination to one of an open state and a ground state by switching a state of one end of the divided unbalanced line opposite one end connected to the unbalanced terminal between a connected state to the first terminal and an open state.

### (Supplementary Note 4)

In the multiband balun described in the supplementary note 2, it is preferable that
the unbalanced line comprises a divided unbalanced line and an adjustment line, the divided unbalanced line being a portion of a side that connects to the unbalanced terminal and having the second line length shorter than the first line length, the adjustment line having a length less than or equal to a difference between the first line length and the second line length,
one end of the adjustment line of the divided unbalanced line side is connected to a first terminal and an other end of the adjustment line is in an open state, and
the first switch switches a state of the unbalanced termination to one of an open state and a ground state by switching a state of one end of the divided unbalanced line opposite one end connected to the unbalanced terminal between a connected state to the first terminal and a ground state.

### (Supplementary Note 5)

In the multiband balun described in the supplementary note 3, it is preferable that
the first switch can switch the state of the one end of the divided unbalanced line opposite one end connected to the unbalanced terminal further among a ground state.

### (Supplementary Note 6)

In the multiband balun described in the supplementary note 4, it is preferable that
the first switch can switch the state of the one end of the divided unbalanced line opposite one end connected to the unbalanced terminal further among an open state.

### (Supplementary Note 7)

The multiband balun described in the supplementary note 3 or 5, further preferably includes:
a second type conversion switch that switches a state of the other end of the adjustment line to one of an open state and a ground state.

### (Supplementary Note 8)

The multiband balun described in the supplementary note 4 or 6, further preferable includes:
a second type conversion switch that switches a state of the other end of the adjustment line to one of an open state and a ground state.

### (Supplementary Note 9)

In the multiband balun described in the supplementary note 7 or 8, it is preferable that
the first switch can switch the state of the one end of the divided unbalanced line opposite one end connected to the unbalanced terminal among a connected state to the first terminal, an open state and a ground state.

### (Supplementary Note 10)

In the multiband balun described in any one of the supplementary notes 1 to 9, it is preferable that
the first switch operates according to a control signal from a controller.

### (Supplementary Note 11)

In the multiband balun described in any one of the supplementary notes 7 to 9, it is preferable that
the second type conversion switch operates according to a control signal from a controller.

### (Supplementary Note 12)

The multiband balun described in the supplementary note 2, further preferably includes:
a second switch, wherein
the second switch switches so that a sum of line lengths of the first balanced line and the second balanced line corresponds to the line length of the unbalanced line.

### (Supplementary Note 13)

In the multiband balun described in the supplementary note 2 or 12, it is preferable that
the first switch switches the unbalanced line between at least one of a first state and a third state and at least one of a second state and a fourth state,
the first state is a state that the line length of the unbalanced line is the first line length and the state of the unbalanced termination is a ground state,
the second state is a state that the line length of the unbalanced line is the first line length and the state of the unbalanced termination is an open state,
the third state is a state that the line length of the unbalanced line is the second line length and the state of the unbalanced termination is a ground state,
the fourth state is a state that the line length of the unbalanced line is the second line length and the state of the unbalanced termination is an open state.

### (Supplementary Note 14)

In the multiband balun described in the supplementary note 1, it is preferable that
the first switch is connected to the unbalanced termination.

### (Supplementary Note 15)

A multiband balun includes:
a first balanced line, one end of the first balanced line being grounded and an other end of the first balanced line being connected to a balanced terminal, the balanced terminal being connected to a balanced circuit;
a second balanced line, one end of the second balanced line being grounded and an other end of the second balanced line being connected to a balanced terminal, the balanced terminal being connected to the balanced circuit;
an unbalanced line, one end of the unbalanced line being connected to an unbalanced terminal, the unbalanced terminal being connected to an unbalanced circuit; and
a type and line length conversion switch, wherein
the unbalanced line includes a divided unbalanced line and an adjustment line, the divided unbalanced line being a portion of a side that connects to the unbalanced terminal and having a second line length shorter than a first line length, the adjustment line having a length less than or equal to a difference between the first line length and the second line length,
one end of the adjustment line of the divided unbalanced line side is connected to a first terminal and an other end of the adjustment line is grounded, and
the type and line length conversion switch is connected to a first end of the divided unbalanced line opposite a second end connected to the unbalanced terminal and can switch a state of the first end between a connected state to the first terminal and an open state.

### (Supplementary Note 16)

A multiband balun includes:
a first balanced line, one end of the first balanced line being grounded and an other end of the first balanced line being connected to a balanced terminal, the balanced terminal being connected to a balanced circuit;
a second balanced line, one end of the second balanced line being grounded and an other end of the second balanced line being connected to a balanced terminal, the balanced terminal being connected to the balanced circuit;
an unbalanced line, one end of the unbalanced line being connected to an unbalanced terminal, the unbalanced terminal being connected to an unbalanced circuit; and
a type and line length conversion switch, wherein
the unbalanced line includes a divided unbalanced line and an adjustment line, the divided unbalanced line being a portion of a side that connects to the unbalanced terminal and having a second line length shorter than a first line length, the adjustment line having a length less than or equal to a difference between the first line length and the second line length,
one end of the adjustment line of the divided unbalanced line side is connected to a first terminal and an other end of the adjustment line is in an open state, and
the type and line length conversion switch is connected to a first end of the divided unbalanced line opposite a second end connected to the unbalanced terminal and switches a state of an unbalanced termination to one of an open and a ground state by switching a state of the first end between a connected state to the first terminal and a ground state.

### (Supplementary Note 17)

In the multiband balun described in the supplementary note 7 or 8, it is preferable that
the second type conversion switch is connected to the other end of the adjustment line.

The disclosure of the PTL 1 above is incorporated herein by reference thereto.

Variations and adjustments of the example embodiments and/or variation examples are possible within the scope of the overall disclosure (including the claims) based on the basic technical concept.

Various combinations and selections of examples and disclosed elements (including the elements in each of the claims, examples, drawings, etc.) are possible within the scope of the claims of the present application. That is, the present disclosure includes various variations and modifications that could be made by those skilled in the art according to the overall disclosure including the claims and the technical concept. In particular, the numerical range described in this document should be interpreted as specifically describing any numerical value or subrange that falls within that range, even if not otherwise stated.

### REFERENCE SIGNS LIST

110: multiband balun
120: multiband balun
130: multiband balun
140: multiband balun
150: multiband balun
160: multiband balun
170: multiband balun
180: multiband balun
210: first balanced line
211: first balanced terminal
220: second balanced line
221: second balanced terminal
230: divided first balanced line
240: first adjustment line
310: unbalanced line
311: unbalanced terminal
312: unbalanced termination
313: termination
314: termination
330: divided unbalanced line
340: second adjustment line
341: terminal
401: ground terminal
402: FET
410: type and line length conversion switch
411: terminal
420: adjustment line
430: second type conversion switch
431: terminal
490: controller
910: Marchand balun
911: frequency characteristic
920: transformer type balun
921: frequency characteristic
ADD: coupled line
FC: primary coil
L1: line length
L2: line length
L3: line length (first line length)
L4: line length (second line length)
L5: line length
L6: line length
OS: open stub
S: coupled line spacing
SC: secondary coil
SS: short stub
SS1: first short stub
SS2: second short stub
SW0: type conversion switch
SW1: first switch
SW2: second switch
SW3: third switch
TM1: terminal
TM2: terminal
W1: line width
W2: line width
W3: line width
fM: center frequency
fM1: center frequency
fM2: center frequency
fT: center frequency
fT1: center frequency
fT2: center frequency
λ: operation wavelength

What is claimed is:

1. A multiband balun, comprising:
a first balanced line, one end of the first balanced line being grounded and an other end of the first balanced line being connected to a balanced terminal, the balanced terminal being connected to a balanced circuit;
a second balanced line, one end of the second balanced line being grounded and an other end of the second balanced line being connected to a balanced terminal, the balanced terminal being connected to the balanced circuit;
an unbalanced line, one end of the unbalanced line being connected to an unbalanced terminal, the unbalanced terminal being connected to an unbalanced circuit; and
a first switch, wherein
the first switch switches a state of an unbalanced termination to one of an open state and a ground state, the unbalanced termination being one end of the unbalanced line opposite the one end connected to the unbalanced terminal.

2. The multiband balun according to claim 1, wherein
the unbalanced line has a first line length, and
the first switch further switches a line length of the unbalanced line to one of the first line length and a second line length, the second line length being shorter than the first line length.

3. The multiband balun according to claim 2, wherein
the unbalanced line comprises a divided unbalanced line and an adjustment line, the divided unbalanced line being a portion of a side that connects to the unbalanced terminal and having the second line length shorter than the first line length, the adjustment line having a length less than or equal to a difference between the first line length and the second line length,
one end of the adjustment line of the divided unbalanced line side is connected to a first terminal and an other end of the adjustment line is grounded, and
the first switch switches a state of the unbalanced termination to one of an open state and a ground state by switching a state of one end of the divided unbalanced line opposite one end connected to the unbalanced terminal between a connected state to the first terminal and an open state.

4. The multiband balun according to claim 2, wherein
the unbalanced line comprises a divided unbalanced line and an adjustment line, the divided unbalanced line being a portion of a side that connects to the unbalanced terminal and having the second line length shorter than the first line length, the adjustment line having a length less than or equal to a difference between the first line length and the second line length,
one end of the adjustment line of the divided unbalanced line side is connected to a first terminal and an other end of the adjustment line is in an open state, and the first switch switches a state of the unbalanced termination to one of an open state and a ground state by switching a state of one end of the divided unbalanced line opposite one end connected to the unbalanced terminal between a connected state to the first terminal and a ground state.

5. The multiband balun according to claim 3, wherein
the first switch can switch the state of the one end of the divided unbalanced line opposite one end connected to the unbalanced terminal further among a ground state.

6. The multiband balun according to claim 4, wherein
the first switch can switch the state of the one end of the divided unbalanced line opposite one end connected to the unbalanced terminal further among an open state.

7. The multiband balun according to claim 3, further comprising:
a second type conversion switch that switches a state of the other end of the adjustment line to one of an open state and a ground state.

8. The multiband balun according to claim 5, further comprising:
a second type conversion switch that switches a state of the other end of the adjustment line to one of an open state and a ground state.

9. The multiband balun according to claim 4, further comprising:
a second type conversion switch that switches a state of the other end of the adjustment line to one of an open state and a ground state.

10. The multiband balun according to claim 6, further comprising:
a second type conversion switch that switches a state of the other end of the adjustment line to one of an open state and a ground state.

11. The multiband balun according to claim 7, wherein
the first switch can switch the state of the one end of the divided unbalanced line opposite one end connected to the unbalanced terminal among a connected state to the first terminal, an open state and a ground state.

12. The multiband balun according to claim 9, wherein
the first switch can switch the state of the one end of the divided unbalanced line opposite one end connected to the unbalanced terminal among a connected state to the first terminal, an open state and a ground state.

13. The multiband balun according to claim 1, wherein
the first switch operates according to a control signal from a controller.

14. The multiband balun according to claim 7, wherein
the second type conversion switch operates according to a control signal from a controller.

15. The multiband balun according to claim 2, comprising:
a second switch, wherein
the second switch switches so that a sum of line lengths of the first balanced line and the second balanced line corresponds to the line length of the unbalanced line.

16. The multiband balun according to claim 2, wherein
the first switch switches the unbalanced line between at least one of a first state and a third state and at least one of a second state and a fourth state,
the first state is a state that the line length of the unbalanced line is the first line length and the state of the unbalanced termination is a ground state,
the second state is a state that the line length of the unbalanced line is the first line length and the state of the unbalanced termination is an open state,
the third state is a state that the line length of the unbalanced line is the second line length and the state of the unbalanced termination is a ground state,
the fourth state is a state that the line length of the unbalanced line is the second line length and the state of the unbalanced termination is an open state.

17. The multiband balun according to claim 1, wherein
the first switch is connected to the unbalanced termination.

18. The multiband balun according to claim 7, wherein
the second type conversion switch is connected to the other end of the adjustment line.

19. A multiband balun, comprising:
a first balanced line, one end of the first balanced line being grounded and an other end of the first balanced line being connected to a balanced terminal, the balanced terminal being connected to a balanced circuit;
a second balanced line, one end of the second balanced line being grounded and an other end of the second balanced line being connected to a balanced terminal, the balanced terminal being connected to the balanced circuit;
an unbalanced line, one end of the unbalanced line being connected to an unbalanced terminal, the unbalanced terminal being connected to an unbalanced circuit; and
a type and line length conversion switch, wherein
the unbalanced line includes a divided unbalanced line and an adjustment line, the divided unbalanced line being a portion of a side that connects to the unbalanced terminal and having a second line length shorter than a first line length, the adjustment line having a length less than or equal to a difference between the first line length and the second line length,
one end of the adjustment line of the divided unbalanced line side is connected to a first terminal and an other end of the adjustment line is grounded, and
the type and line length conversion switch is connected to a first end of the divided unbalanced line opposite a second end connected to the unbalanced terminal and can switch a state of the first end between a connected state to the first terminal and an open state.

20. A multiband balun, comprising:
a first balanced line, one end of the first balanced line being grounded and an other end of the first balanced line being connected to a balanced terminal, the balanced terminal being connected to a balanced circuit;
a second balanced line, one end of the second balanced line being grounded and an other end of the second balanced line being connected to a balanced terminal, the balanced terminal being connected to the balanced circuit;
an unbalanced line, one end of the unbalanced line being connected to an unbalanced terminal, the unbalanced terminal being connected to an unbalanced circuit; and
a type and line length conversion switch, wherein the unbalanced line includes a divided unbalanced line and an adjustment line, the divided unbalanced line being a portion of a side that connects to the unbalanced terminal and having a second line length shorter than a first line length, the adjustment line having a length less than or equal to a difference between the first line length and the second line length,
one end of the adjustment line of the divided unbalanced line side is connected to a first terminal and an other end of the adjustment line is in an open state, and
the type and line length conversion switch is connected to a first end of the divided unbalanced line opposite a second end connected to the unbalanced terminal and switches a state of an unbalanced termination to one of an open and a ground state by switching a state of the first end between a connected state to the first terminal and a ground state.
